(19) United States
(12) Patent Application Publication
(10) Pub. No.: US 2008/0231284 A1
(43) Pub. Date: Sep. 25, 2008

(54) Method and Device for Detdermining the Ageing of a Battery

(76) Inventors: Peter Birke, Glienicke/Nordbahn (DE); Michael Keller, Baden-Baden (DE); Manfred Malik, Penzberg (DE)

Correspondence Address: CONTINENTAL TEVES, INC., ONE CONTINENTAL DRIVE, AUBURN HILLLS, MI, 48326-1581, US

(21) Appl. No.: 12/091,202

(22) PCT Filed: May 17, 2006
(86) PCT No.: PCT/DE06/00847

§ 371 Date: Apr. 23, 2008

(30) Foreign Application Priority Data
Oct. 28, 2005 (DE) 10 2005 052 862.7

(51) Int. Cl. G01R 31/36; G01N 27/416

(52) U.S. Cl. 324/426

(57) ABSTRACT

Disclosed is a method for determining the ageing (SoH) of a battery (1, 2), such as a lead battery, a nickel metal hydride battery, a lithium ion battery or a capacitor for a vehicle. Several parameters (5.1 to 5.n) of the battery (1, 2) are detected or determined and two parameters (5.1 to 5.n) are predefined as a pair of parameters (5.1 to 5.n, 5.1 to 5.n) and are correlated in such a way that the parameter ranges that form the basis of each parameter (5.1 to 5.n) and value pairs (X1, Y1 to Xn, Ym) of the predefined pair of parameters (5.1 to 5.n, 5.1 to 5.n) that result from said ranges are weighted in classes.

### BACKGROUND OF THE INVENTION

The invention relates to a method and an apparatus for determining the ageing in particular of a secondary battery for a vehicle. Opposite to a non-rechargeable primary battery a secondary battery refers to a rechargeable storage (also called accumulator or secondary storage). In the following a battery means a secondary battery. In particular a lead battery, a nickel metal hydride battery, a lithium ion battery or another suitable rechargeable storage unit, such as a capacitor, is used as a vehicle battery. The ageing of the battery refers in particular to the degree of the ability of the battery to provide a required power.

A method for determining the ageing of a vehicle battery is used in particular for traction batteries of electric vehicles or hybrid vehicles, as they continuously age by storage and operation. In particular, the reduction of the storable charge quantity, which is associated with an increasing service life, and the reduction of the ability of the battery to provide power is of substantial importance for the user of the vehicle.

The ageing of the battery is usually determined by information, such as the frequency distribution from continuous measurements of voltage, current and temperature. This possibly leads to large storage requirements of the continuously detected measured variables. Beyond that, the processing expenditure associated with the analysis of the measured variables detected in time is very high. Further, an adjustment of the analysis method to amended environmental conditions and a resulting recalibration of the measuring and analysis methods is particularly time and storage consuming.

It is, therefore, the object of the invention to indicate a particularly simple method for determining the ageing of a battery. Beyond that, a particularly suitable apparatus for determining the ageing of a battery is to be indicated.

### SUMMARY OF THE INVENTION

1) In view of the method the object is solved by determining the ageing (SoH) of a battery (1, 2), such as a nickel metal hydride battery for a vehicle, in which several parameters (5.1 to 5.n) of the battery (1, 2) are detected and/or determined, wherein two respective parameters (5.1 to 5.n) are predefined as a pair of parameters (5.1 to 5.n, 5.1 to 5.n) and are correlated in such a way that the parameter ranges that form the basis of each parameter (5.1 to 5.n) and value pairs (X1, Y1 to Xn, Ym) of the predefined pair of parameters (5.1 to 5.n, 5.1 to 5.n) that result from said ranges are weighted in classes. The object is also solved by an apparatus for determining the ageing (SoH) of a battery (1, 2), in particular a nickel metal hydride battery for a vehicle, comprising storage (7), in which several parameters (5.1 to 5.n) of the battery (1, 2) are deposited such that two respective parameters (5.1 to 5.n) are correlated as a pair of parameters (5.1 to 5.n, 5.1 to 5.n) and that the parameter ranges that form the basis of each parameter (5.1 to 5.n) and value pairs (X1, Y1 to Xn, Ym) of the predefined pair of parameters (5.1 to 5.n, 5.1 to 5.n) that result from said ranges are weighted in classes.

With the method for determining the ageing of a battery, in particular a nickel metal hydride battery or a lithium ion battery for a vehicle, in particular the state of charge, temperature, charging current and/or discharging current are detected or determined as parameters of the battery, wherein two respective parameters are predefined as a pair of parameters and are correlated in such a way that the parameter ranges that form the basis of each parameter and value pairs of the predefined pair of parameters that result from said ranges are weighted in classes. Such a classification and weighting of pairs of measured values allows for a simple and quick and storage place saving analysis of the ageing of the battery, by processing measured values detected in time on the basis of correlated value pairs and consequently by forming a classified and/or weighted value for further analysis and processing. Thus, an ageing factor can be determined by simple comparative calculation. Moreover, on the basis of the values of the ageing factor the ageing of the battery can be differentiated into predefined failure modes. This allows for a further reduction of the storage requirements and of the analysis expenditure.

Preferably, each parameter is classified such that its in particular admissible parameter range is subdivided into a predefined number of classes. Here, the number of classes is defined by the respective influence and effect of the concerned parameter onto the ageing of the battery. Thus, a battery comprises a behavior which is very strongly dependent on temperature. In particular, the capacity and the state of charge of a nickel metal hydride battery (in short also called NiMH battery) strongly depend on the ambient temperature due to the hydrogen storage alloy used in the negative electrode. High temperatures of >45° C. initiate a release of hydrogen and impairment of the charge capacity by the negative electrode, as with increasing temperature a hydrogen counter-pressure is developed. With very low temperatures of <−10° C. hydrogen with a worse removal and integration kinetics is released and received by the negative electrode. In other words: With metal hydride storage alloys hydrogen is bound well in such an alloy at ambient temperatures, however, by heat it is more and more re-expelled. Therefore, for example the parameter range of the state of charge and/or the temperature is classified into seven or eight classes with a predefined step size of 5% to 20% or of 5° C. to 20° C., respectively, within a parameter range of <30% to >95% or <−25° C. to >55° C., respectively.

In order to receive a statement about the ageing of the battery instead of the extensive calculation expenditure of stored measured values by simply comparing actual values with deposited values, a weighting factor related to classes is assigned to each value pair of a pair of parameters. For example, if the state of charge and the temperature are correlated as a pair of parameters and their parameter ranges are subdivided into classes, thus each value pair, e.g. state of charge <30% and temperature <−25° C. or state of charge >95% and temperature >55° C. is provided with an associated weighting factor. Here, the weighting factor corresponds to the ageing factor determined on the basis of empirical values and in particular by means of a battery model of the correlated parameters—state of charge and temperature—and their influence onto the ageing of the battery.

Advantageously, those value pairs with a high weighting factor are classified as the data affecting the service life of the battery. Beyond that, these value pairs with a high weighting factor can be identified as failure modes. Failure modes refer in the following in particular to events substantially affecting the service life of the battery, which represent those parameter ranges, which are occupied with a high weighting.

Alternatively or additionally those value pairs with a low weighting factor are classified as function-relevant or operation-appropriate data. Here, those value pairs are concerned, which lie in the normal and operation-admissible parameter range, and which effect an average or only small ageing of the battery.

For a simple analysis of the battery condition during a preceding period a state meter associated to the concerned value pair is increased upon existence of current actual values or instantaneous values, which correspond to one of the predefined value pairs. This allows for a simple consideration of the preceding service or operating age of the battery when determining the current ageing. In this case, with the method according to invention merely a value of a state meter is deposited instead of the complex deposit of a plurality of measured values and their times of detection.

In order to be able to determine the ageing of the battery in addition or as an alternative for simply identifying the failure modes of the battery, an individual ageing factor is determined for all value pairs of a pair of parameters on the basis of the weighting factor and the state meter. This ageing factor, which is formed for a respective pair of parameters, e.g. state of charge and temperature, temperature and self-discharge conversion, state of charge and charge conversion, charging current and charge conversion, time and charge conversion, here reflects the influence of the respective pair of parameters onto the ageing of the battery. Depending on the degree of the influence of the respective pair of parameters and their values the respective ageing factor of a pair of parameters can be weighted.

Beyond that, preferably on the basis the sum of the weighted individual ageing factors of all pair of parameters a total ageing factor is determined for the battery. For taking into consideration all parameters affecting the ageing of the battery that or the individual ageing factors and/or the total ageing factor are or will be used when determining the ageing of the battery.

In a further form of embodiment of the invention the ageing can be taking into consideration when determining the state of function of the battery. The values of the ageing, the state of charge and/or the state of function of the battery can be supplied to a controller for an operation of the battery which is as gentle as possible. Here, the values with a battery management deposited in the controller for adjusting charging processes or discharging processes of the battery at an optimal operating point are taken into consideration.

With regard to the apparatus for determining the ageing of a battery this comprises a storage, in which several parameters of the battery are deposited such that two respective parameters are correlated as a pair of parameters and that parameter ranges that form the basis of each parameter and value pairs of the predefined pair of parameters that result from said ranges are weighted in classes. Such a deposit of a combined value for value pairs instead of the deposit of individual values and their times of detection allow for a clear reduction of the storage place and for a faster analysis and evaluation of the deposited data on the basis of current data, such as actual values and instantaneous values.

Several storage units are provided for a respective pair of parameters to quickly find parameters affecting the ageing of the battery. Advantageously, for a parameter a number of storage fields corresponding to a predefined number of classes is provided in a first storage unit. In a second storage unit for a respective pair of parameters a number of storage fields for a weighting factor is provided. Moreover, for taking into consideration the preceding values a state meter is assigned to each deposited value pair, on the basis of which meter the frequency of the occurrence of the value pair is detected. Thus, instead of extensive storage place requirements for depositing a plurality of individual measured values and their times of detection merely the storage place for a weighting factor and a state meter is necessary.

The advantages achieved with the invention involve particular the fact that by classifying and weighting parameter ranges of two correlated parameters, which affect the ageing of the battery, a simple and quick possibility for determining the ageing of the battery on the basis of identifying failure conditions of the battery is given. Beyond that, the weighting and classification of parameter ranges of individual parameters affecting the service life of the battery allow for a simple and quick adjustment of the method to amended environmental conditions. In particular, the battery can be adapted to the new and amended environmental conditions and can be newly calibrated by changing the weighting and the classes. The method can be easily adapted irrespective of the battery type or of the battery technology. Predefining the number of failure modes and the number of classes of the individual parameters allows for a determination of the ageing of the battery adapted to the respective type and to the respective technology. The predefined weighting of the value pairs of two parameters takes into consideration the battery type or the battery technology or the preceding service life on the basis of expert knowledge. Improvements of the state of the battery, e.g. by compensating charges, can be simply and quickly considered by adapting the concerned weighting factor.

### BRIEF DESCRIPTION OF THE DRAWINGS

Examples of embodiments of the invention are described in detail on the basis of a drawing, in which

FIG. 1 shows schematically an apparatus for determining the ageing of a battery,

FIG. 2 shows schematically a battery management system with an apparatus for determining the ageing of the battery,

FIG. 3 to 4 show a form of embodiment for a storage for depositing pairs of parameters weighted in classes,

FIG. 5 to 6 show a form of embodiment for storage units for classifying parameters and for depositing weighting factors, and

FIG. 7 to 11 show further forms of embodiment for storages for depositing further pairs of parameters weighted in classes.

### DETAILED DESCRIPTION OF THE DRAWINGS

Appropriate elements are provided in all figures with the same reference numerals.

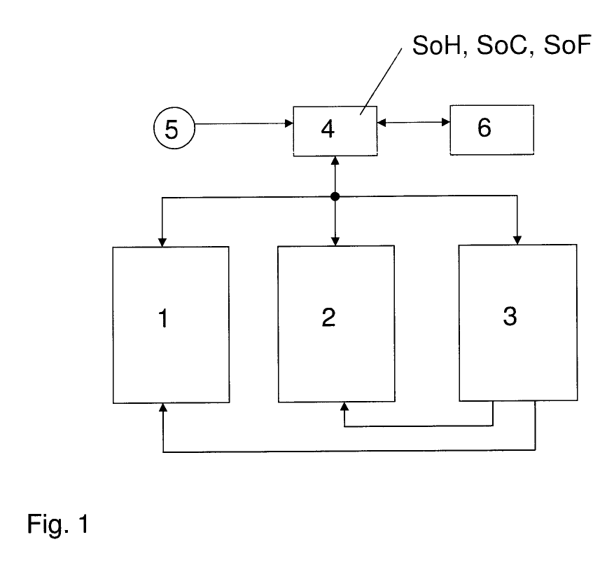

FIG. 1 shows an apparatus for determining the ageing SoH of a battery 1 for a vehicle. The battery 1 can be a traction battery for a hybrid vehicle. For example a nickel metal hydride battery, a lithium ion battery or another suitable battery is used as a traction battery. Beyond that, a further secondary battery 2 in form of a lead acid battery can be provided. The batteries 1 and 2 are charged during driving via a generator 3.

For controlling the batteries 1 and 2 the apparatus comprises a controller 4, for example a battery controller or a vehicle electrical system controller, which is connected to the battery 1 and to the secondary battery 2 as well as to the generator 3. By means of the controller 4 for example the voltage U, temperature T, current 1, state of charge SoC, charging and discharging times t, are detected and determined as parameters 5.1 to 5.n of the battery 1 and of the secondary battery 2.

For this purpose appropriate sensors are provided, the measured values of which are supplied to the controller 4. Alternatively or additionally, data or information from preceding measuring and processing methods, e.g. estimation and observation methods, model and parameter identification methods, temperature model methods, history tables, impedance measurements, self-learning methods can be supplied. In particular, the ambient temperature is detected as temperature. Alternatively or additionally also the respective battery or cell temperature can be detected as temperature.

Furthermore, for determining the ageing SoH of the battery 1 or 2, further information and data are necessary, such as e.g. surface passivation of the electrodes of the battery, creeping dehydration of the battery cells, contact losses and an increase of cell impedances caused by these processes as well as reduction of the battery capacity related to the same discharge cutoff voltage. This information and data can be detected indirectly, for example via measurement of the cell impedance, and can be supplied to the controller 4 and can be respected when determining the ageing SoH by means of a model-based estimation process. Also deviations of the state of charge of individual battery cells within a series connection can be provided for, a clearing of the deviations caused by compensating charge by means of the controller 4 being determined and considered on the basis of algorithms.

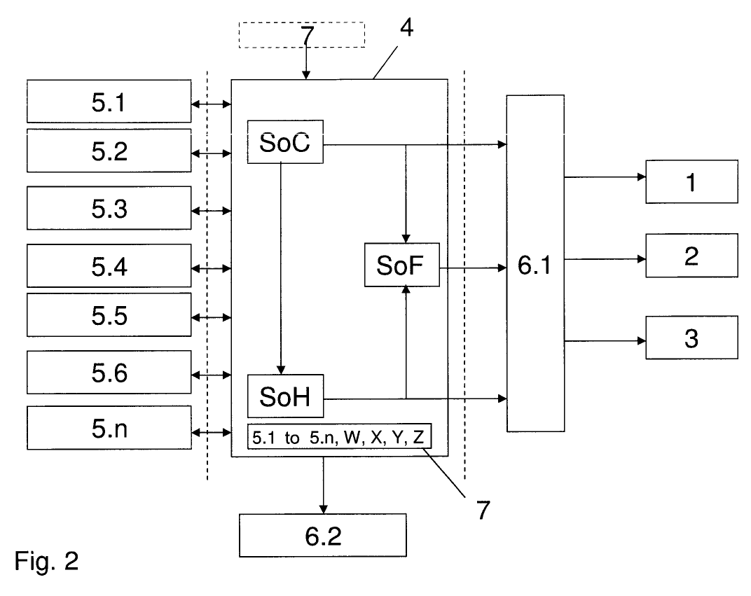

To allow for further vehicle-relevant or battery-relevant parameters, e.g. vehicle speed or values for brake energy recuperation, the controller 4 can be connected for example to other controllers 6, to a hybrid controller 6.1 and/or to a fan controller 6.2, as this is shown as an example in FIG. 2.

In the conventional operation of a vehicle for a sufficient supply of the electrical consumers, such as ignition, fuel injection, lighting, heating, air conditioning system, brakes, the battery is continuously monitored with regard to its state of charge SoC, instantaneous temperature T, discharging current Ia and charging current Ie.

For reduction of the storage place requirements and simple and quick determination of the ageing SoH of the battery 1, at least one storage 7 is provided according to invention, which is formed separately or is integrated into the controller 4.

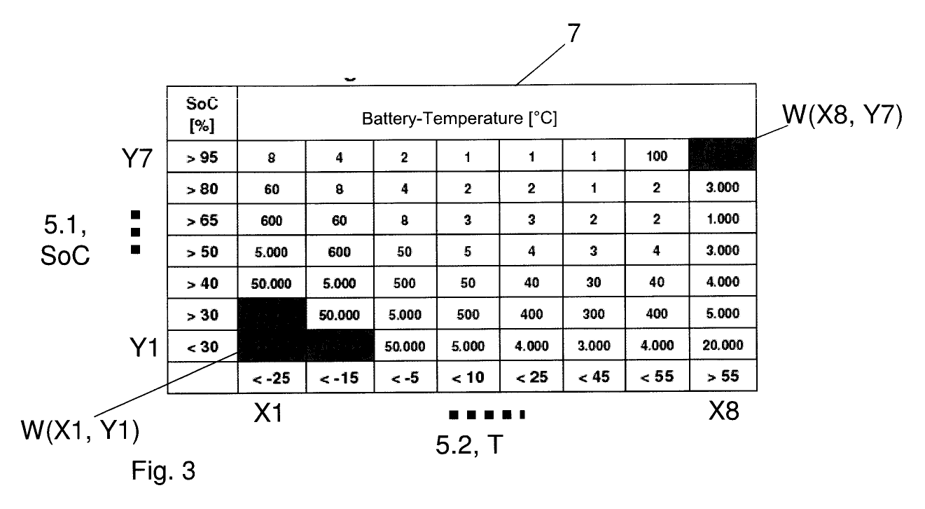

One example of embodiment for the structure of the storage 7 is shown in detail in FIG. 3. In the storage 7 two parameters 5.1 and 5.2, e.g. the state of charge SoC and the temperature T are correlated as a pair of parameters. Here, for the respective parameter 5.1 or 5.2, their parameter ranges are subdivided into a predefined number of classes Y1 to Y7 or X1 to X8. For example for the parameter 5.1—the state of charge SoC—there are seven classes Y1 to Y7 for the following parameter ranges <30%, >30%, >40%, >50%, >65%, >80% and >95%. For the parameter 5.2—the temperature T—there are eight classes X1 to X8 with the following parameter ranges: <−25° C., <−15° C., <−5° C., <10° C., <25° C., <45° C., <55° C. and >55° C.

The parameter ranges of the two parameters 5.1 and 5.2 are selected and predefined here such that they are subdivided into classes X1, X2, X7, Y1, Y2, Y8 highly affecting the service life of the battery 1 and into function-relevant classes X5, X6 and Y4 to Y6. Depending on the battery type, battery technology, environmental conditions and/or age of the battery 1, the number of the classes X1 to Xn or Y1 to Ym, as well as their stages, i.e. the parameter ranges, can be changed and adapted dynamically.

Here, a weighting factor W (X1, Y1; . . . ; Xn, Ym) is assigned to each value pair X1, Y1 to Xn, Ym of the correlated parameters 5.1 and 5.2. The weighting factor W corresponds to the ageing influence of the parameters 5.1 and 5.2 onto the battery 1. The weighting factor W is based on expert knowledge and can be adapted to the respective battery type, the battery technology or to any other conditions.

In this context, those value pairs X1, Y1; X1, Y2; X2, Y1; X8, Y7; with a high weighting factor W of for example 100,000 are evaluated. The concerned value pairs X1, Y1; X1, Y2; X2, Y1; X8, Y7; represent value ranges which strongly affect the service life of the battery 1. These value pairs X1, Y1; X1, Y2; X2, Y1; X8, Y7; strongly affecting the service life of the battery 1 can be identified beyond that as failure modes.

If instantaneous or actual values of the parameters 5.1 and 5.2 occur, which correspond to the concerned value pairs X1, Y1; X1, Y2; X2, Y1; X8, Y7, an associated failure mode is identified based on the allocation of the actual values to the value pairs X1, Y1; X1, Y2; X2, Y1; X8, Y7.

For example the following states of value pairs X1, Y1 to Xn, Ym are identified as failure modes.

The following failure modes for a metal hydride battery can occur:
I. High temperature T and high state of charge SoC of up to 100% (=failure mode I) or
II. High charging current Ie and high state of charge SoC (=failure mode II) lead to:
   1. 0₂-development at the positive electrode, Ni (OH)₂;
   2. H₂-development at the negative electrode, storage alloy;
   3. O₂- and H₂-development (detonating gas);
   4. High self-charge.
   This can result in the following irreversible events at the battery 1:
      Oxidation of the negative electrode;
      Oxidation of the separator;
      Dehydration (H2O-loss), if pressure control valve opens, loss of capacity;
      Increase of internal resistance;
      Heat damages;
      Explosion;
   Beyond that, reversible events can occur in succession:
      Loss of capacity;
      Charge efficiency drops.
III. High temperature T and state of charge SoC <80% (=failure mode III) lead to:
   1. Correlation end of charging (=“voltage hunch”) with lower states of charge SoC;
   2. Self-discharge.
   This can lead to reversible damages:
      Available capacity drops;
      Charge efficiency drops.
IV. Low temperature T and moderate load of the battery (=failure mode IV) lead to:
   1. Strong constraint of the storage alloy of the negative electrode (kinetics strongly restrained);
   2. Polarizations at the phase interface electrode/electrolyte/ separator.
   This can lead to reversible damages:
      Charging/discharging difficult.
V. Low temperature T and high current (=failure mode V) lead to:
   1. Damage of the storage metal matrix.
   This can lead to irreversible and reversible damages:
      Available capacity drops;
      Balance of recombination cycle is disturbed;
   0₂-Development at the positive electrode.
VI. Excessive current (failure mode VI) lead to:
   1. Polarization;
   2. Power loss.
   This can lead to irreversible and reversible damages:
      Damage of the grid structure of the storage electrodes;
      Overheating of the cells (reversible/irreversible);
      Damage of the cell-internal and external connectors.
VII. Very deep state of charge SoC (=failure mode VII) or
VIII. High discharging current and low state of charge SoC (=failure mode VII) lead to:
   1. Deep discharge;
   2. Running down.
   This might lead to irreversible and reversible damages:
      in case of short deep discharge to reversible damages;
      in case of long deep discharge to damages of the conductivity matrix of the positive electrode (=irreversible damage);
      short pole reversal (reversible); —
      longer pole reversal (irreversible);
      risk of overheating;
      formation of detonating gas;
      activation of the safety valve.
IX. Component tolerances lead to:
   1. Divergency of the states of charge SoC of the solitary cells of the battery of a series interconnection.
   This might result in irreversible and reversible damage:
      in case of short deep discharge to reversible damages;
      in case of long deep discharge to damages of the conductivity matrix of the positive electrode (=irreversible damage);
      short pole reversal (reversible); —
      longer pole reversal (irreversible);
      risk of overheating;
      formation of detonating gas;
      activation of the safety valve;
      solitary cells can exceed a state of charge SoC of 100% during charging.

These states identified as failure modes I to IX of the battery 1 are evaluated on the basis of the value pairs X1, Y1 to Xn, Ym of the parameters 5.1 and 5.2, in particular of the temperature T and the state of charge SoC with a high weighting factor W of for example 100,000 and 500,000.

Here, the classes Y1 to Ym and X1 to Xn as well as the weighting factors W are deposited in the storage 7 merely on the basis of integers. For example for the weighting factor W within a range from 1 to 500,000.

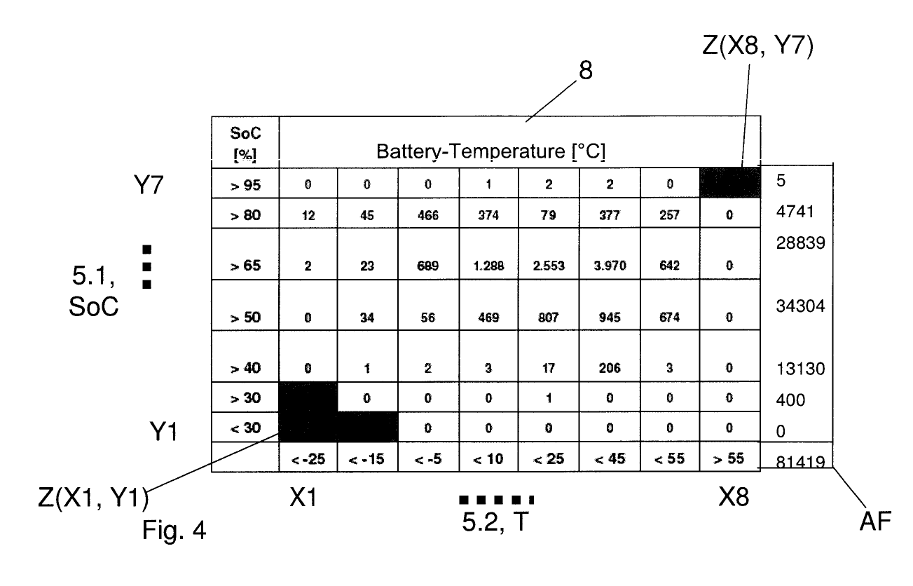

In a further storage 8, which is shown in detail in FIG. 4, assigned state meters Z (X1, Y1; . . . ; Xn, Ym) are deposited for the value pairs X1, Y1 to Xn, Ym of the correlated parameters 5.1 and 5.2. In this connection, the state meter Z serves for considering the preceding states of the battery 1 and thus of the history of the states of the battery 1. Upon existence of instantaneous values or actual values of the parameters 5.1 and 5.2, which correspond to one of the predefined value pairs X1, Y1 to Xn, Ym, the state meter Z (X1, Y1; . . . ; Xn, Ym) assigned to the concerned value pair X1, Y1 to Xn, Ym is increased. In other words: The more frequently a state occurred, the higher the meter reading of the concerned state meter Z. In FIG. 4 for example, the value pair X6, Y5 comprises the highest meter reading with 3,970.

In the storage 8 further storage fields for determining an ageing factor AF assigned to this pair of parameters 5.1 and 5.2 are to be defined in order to be able to determine the influence of occurrence of the value pairs X1, Y1 to Xn, Ym onto the service life and the ageing SoH of the battery. For this purpose, the respective weighting factor W (X1, Y1; . . . ; Xn, Ym) is multiplied with the assigned state meter Z (X1, Y1; . . . ; Xn, Ym) and their sum is calculated. The resulting ageing factor AF corresponds to the ageing influence of the observed parameters 5.1 and 5.2 onto the battery 1.

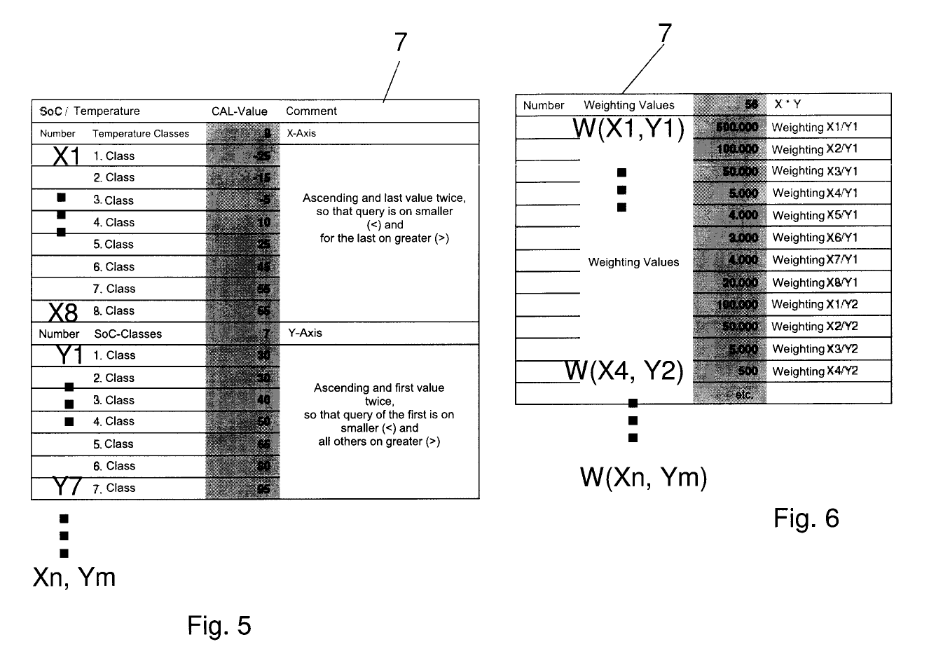

FIGS. 5 and 6 show in detail the storage fields of the storage 7 for presetting and determining the classes X1 to Xn or Y1 to Ym of the observed parameters 5.1 and 5.2 or for presetting and determining the values of the assigned weighting factors W (X1, Y1 to Xn, Ym).

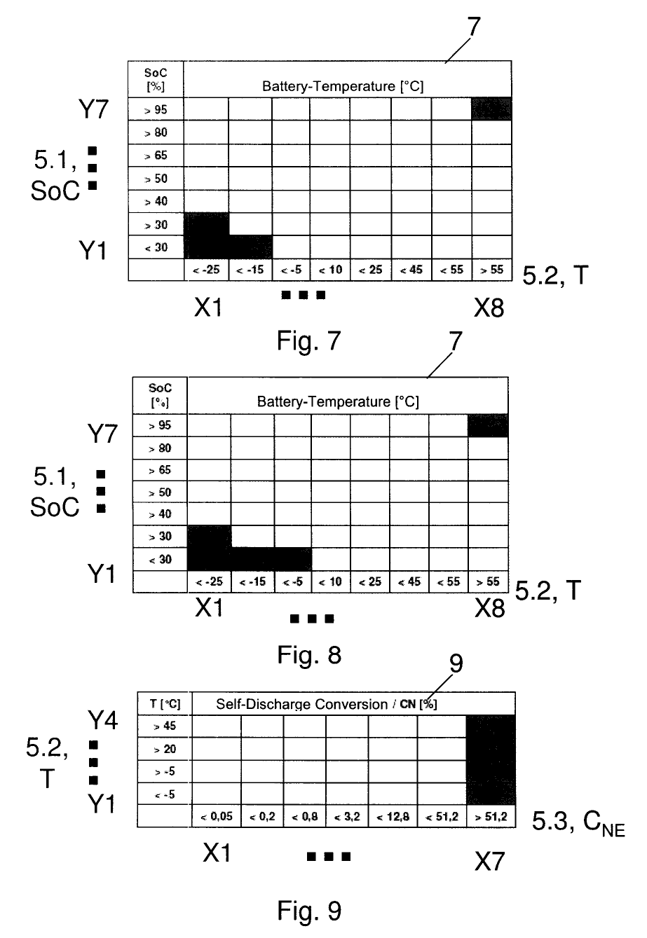

FIGS. 7 and 8 show different forms of embodiment of the storage 7, which refer to different operating modes of the battery 1.

Thus, in FIG. 7 the assignment of state of charge SoC and temperature T and the concerned failure modes in the normal operation of the battery 1 are shown as an example. In this context, upon occurrence of one of the value pairs X1, Y1; X1, Y2; X2, Y1 or X8, Y7, a failure mode is identified. For monitoring the battery 1 in the normal operation the current actual values of the parameters 5.1 and 5.2 are detected and determined at least every 0.5 h.

FIG. 8 shows an example of embodiment for a battery 1 in the wakeup mode. In addition to the failure modes predefined in the normal operation, in the wakeup mode a failure mode is identified upon occurrence of the value pair X3, Y1. In the wakeup mode the current actual values of the parameters 5.1 and 5.2 are detected and determined at least every 1.0 h.

FIGS. 9 to 11 show further examples of embodiment for pairs of parameters 5.1 to 5.n, which are correlated, classified and weighted and for which a respective ageing factor AF is determined. In addition, the individual ageing factor AF of each pair of parameters 5.1 to 5.n can be weighted. The sum of all individual and if applicable weighted ageing factors AF of all pairs of parameters 5.1 to 5.n results in the total ageing factor gAF, which represents the ageing SoH of the battery 1.

In FIG. 9 by way of example the temperature T and self-discharge conversion C_{NE} are deposited in a further storage 9 as a further pair of parameters 5.2 and 5.3. This parameter relation serves to identify failure modes and their influences onto the ageing of the battery 1 in the neutral mode of battery 1, if the latter is in the neutral mode for example between two wakeup modes. For this observed pair of parameters 5.2 and 5.3 a closed circuit load is identified as a failure mode.

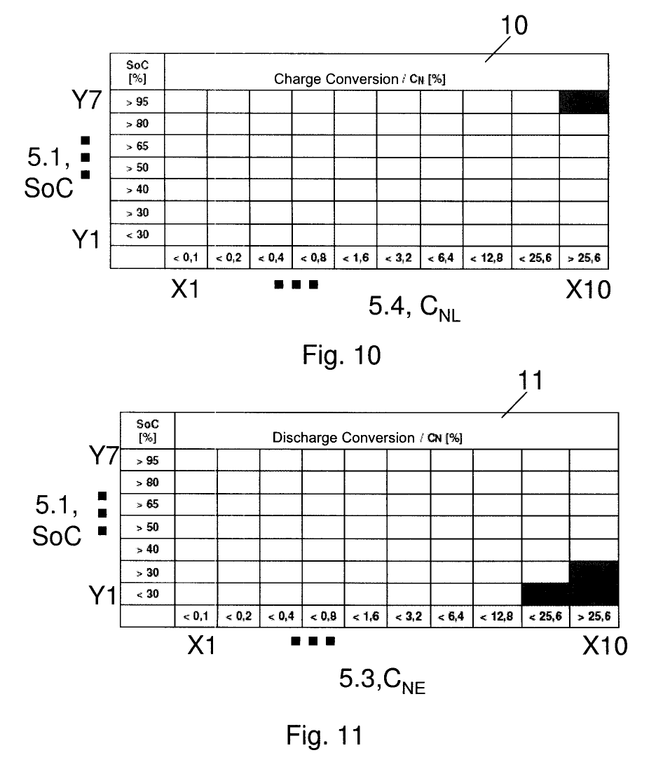

In FIG. 10 by way of example the charge conversion C_{NL} and the state of charge SoC are deposited in a further storage 10 as a further pair of parameters 5.4 and 5.1. This parameter relation serves to identify failure modes and their influences onto the ageing of the battery 1 when charging the battery 1, if the latter is for example recharged between two discharges. The integrated charge conversion C_{NL} is correlated between two discharges to the state of charge SoC of the battery 1. For this observed pair of parameters 5.4 and 5.1 overcharging or fatigue is identified as a failure mode (=value pair X10, Y7).

Beyond that, further parameter relations and their influence onto the ageing of the battery 1 can be considered. For example, in further storages the following pairs of parameters can be considered when charging the battery 1:
maximum charging current during the charge conversion;
average charging current during the charge conversion;
time period of the charge conversion;
maximum charging current dependent on the temperature.

For the additional or alternatively observed pairs of parameters again failure modes are predefined and are quickly and simply identified on the basis of the currently detected actual values.

In FIG. 11 by way of example the charge conversion C_{NE} and the state of charge SoC are deposited in a further storage 11 as a further pair of parameters 5.3 and 5.1. This parameter relation serves to identify failure modes and their influences onto the ageing of the battery 1, when discharging the battery 1, if the latter is re-discharged for example between two charges. The integrated charge conversion C_{NE} or the height of the discharge depth DoD (DoD=depth of discharge) between two charges is correlated with the state of charge SoC of the battery 1. For this observed pair of parameters 5.3 and 5.1 a deep discharge, running down or fatigue are identified as a failure mode (=value pair X9, Y1; X10, Y1; X10, Y2). In case of lead batteries the service life reduces considerably with rising discharge depth DoD, e.g. 100% DoD 500 cycles or 5% DoD 50000 cycles.

When discharging the battery 1, moreover further parameter relations and their influence onto the ageing of the battery 1 can be considered:
maximum discharging current during the discharge conversion;
average discharging current during the discharge conversion;
time period of the discharge conversion;
maximum discharging current depending on the temperature.

For the additional or alternatively observed pairs of parameters again failure modes are predefined and are quickly and simply identified on the basis of the currently detected actual values.

For considering component tolerances and their effects onto the ageing of the battery 1 the following parameter relations can be set up and considered when determining the ageing SoH on the basis of determination of the respective ageing factor AF:
deviation of the module voltages from the average value in the wakeup mode;
deviation of the module voltages from the average value during charging;
deviation of the module voltages from the average value during discharging.

Beyond that, as further parameters 5.n an equalizing charge, a resetting of the ageing value can be considered and correlated with other parameters. Also storage of the maximum deviation and increase of the equalizing charge meter can be considered when determining the ageing SoH.

As further parameters the internal resistance of the battery 1 can be determined on the basis of the relation between discharging current and voltage. Also the capacity C can be determined on the basis of the relation between charge conversion C_{NL} and amendment of the state of charge.

The ageing SoH determined on the basis of the individual ageing factors AF and/or the total ageing factor gAF can be shown herein differentiated manner. Depending on the determined degree of the ageing SoH an appropriate message is shown to the user of the vehicle, e.g. graduated, such as follows:
1. full operability,
2. check of battery 1 recommended with the next service,
3. conduct service
4. possible loss.

Beyond that, depending on the determined degree of the ageing SoH by means of the controller 4 an equalizing charge of the battery 1 can be activated, charging and thus increasing the state of charge SoC and/or restricting the state of function of the battery 1 can be effected. In case of a very bad condition of the battery the latter can also be provided for an impulse start only.

The invention is not limited to the example of embodiments described here. Thus, further pairs of parameters or value pairs for different battery types can be formed. In case of use of a double layer capacitor as a rechargeable storage for example the pair of parameters “cell voltage” and “condenser temperature” can be the crucial ageing criterion (dissociation of the electrolyte). In the quiescent mode this value pair is linked additionally to a time parameter.

### LIST OF REFERENCE NUMERALS

1 Battery
2 Battery
3 Generator
4 Controller
5.1 to 5.n Parameters
6.1 Hybrid controller
6.2 Fan control
SoC State of charge
SoH Ageing
SoF State of function
T Temperature
CN Nominal capacity
X1 to Xn Parameter classes
Y1 to Ym Parameter classes
W Weighting factor
Z State meter

### LIST OF REFERENCE NUMERALS

1 Battery
2 Battery
3 Generator
4 Controller
5.1 to 5.n Parameters
6.1 Hybrid controller
6.2 Fan control
SoC State of charge
SoH Ageing
SoF State of function
T Temperature
CN Nominal capacity
X1 to Xn Parameter classes
Y1 to Ym Parameter classes
W Weighting factor
Z State meter

1-17. (canceled)

18. A method for determining the ageing (SoH) of a battery (1, 2), comprising:
determining in which several parameters (5.1 to 5.n) of the battery (1, 2), wherein two respective parameters (5.1 to 5.n) are predefined as a pair of parameters (5.1 to 5.n, 5.1 to 5.n) and are correlated in such a way that the parameter ranges that form the basis of each parameter (5.1 to 5.n) and value pairs (X1, Y1 to Xn, Ym) of the predefined pair of parameters (5.1 to 5.n, 5.1 to 5.n) that result from said ranges are weighted in classes.

19. A method according to claim 18, wherein each parameter (5.1 to 5.n) is classified such that its parameter ranges are subdivided into a predefined number of classes (X1 to Xn; Y1 to Ym).

20. A method according to claim 18, wherein a weighting factor (W (X1, Y1) to W (Xn, Ym)) is class-related assigned to each value pair (X1, Y1 to Xn, Ym).

21. A method according to claim 20, wherein the value pairs (X1, Y1 to Xn, Ym) with a high weighting factor (W (X1, Y1) to W (Xn, Ym)) are classified as the data affecting the service life of the battery (1, 2).

22. A method according to claim 21, wherein those value pairs (X1, Y1 to Xn, Ym) with a low weighting factor (W (X1, Y1) to W (Xn, Ym)) are classified as function-relevant data.

23. A method according to claim 14, wherein upon existence of current actual values, which correspond to one of the predefined value pairs (X1, Y1 to Xn, Ym), a meter (Z (X1, Y1) to Z (Xn, Ym)) assigned to the concerned value pair (X1, Y1 to Xn, Ym) is increased.

24. A method according to claim 23, wherein on the basis of the weighting factor (W (X1, Y1) to W (Xn, Ym)) and the state meter (Z (X1, Y1) to Z (Xn, Ym)) for all value pairs (X1, Y1 to Xn, Ym) of a pair of parameters (5.1 to 5.n, 5.1 to 5.n) an individual ageing factor (AF) is determined.

25. A method according to claim 24, wherein a respective ageing factor (AF) of a pair of parameters (5.1 to 5.n, 5.1 to 5.n) is weighted.

26. A method according to claim 25, wherein based on a sum of the weighted individual ageing factors (AF) of all pairs of parameters (5.1 to 5.n, 5.1 to 5.n) a total ageing factor (gAF) for the battery (1, 2) is determined.

27. A method according to claim 26, wherein at least one of the individual ageing factors (AF) and the total ageing factor (gAF) is considered when determining the ageing (SoH) of the battery (1, 2).

28. A method according to claim 27, wherein the ageing (SoH) is considered when determining the state of function (SoF) of the battery (1, 2).

29. A method according to claim 28, wherein at least one of the ageing (SoH), state of charge (SoC) and the state of function (SoF) is supplied to a controller (4).

30. An apparatus for determining the ageing (SoH) of a battery (1, 2), the apparatus comprising:
storage (7), in which several parameters (5.1 to 5.n) of a battery (1, 2) are deposited such that two respective parameters (5.1 to 5.n) are correlated as a pair of parameters (5.1 to 5.n, 5.1 to 5.n) and that the parameter ranges that form the basis of each parameter (5.1 to 5.n) and value pairs (X1, Y1 to Xn, Ym) of the predefined pair of parameters (5.1 to 5.n, 5.1 to 5.n) that result from said ranges are weighted in classes.

31. An apparatus according to claim 30, wherein several storage units (7 to 10) are provided for a pair of parameters (5.1 to 5.n, 5.1 to 5.n).

32. An apparatus according to claim 31, wherein in a first storage unit a number of storage fields corresponding to a predefined number of classes (x1 to Xn, Y1 to Ym) is provided for a parameter (5.1 to 5.n).

33. An apparatus according to claim 31, wherein in a second storage unit for a respective pair of parameters a number of storage fields is provided for a weighting factor (W (X1, Y1) to W (Xn, Ym)).

34. An apparatus according to claim 30, wherein a state meter (Z (X1, Y1) to Z (Xn, Ym)) is assigned to each deposited value pair (X1, Y1 to Xn, Ym).
